(19) United States
(12) Patent Application Publication
(10) Pub. No.: US 2025/0223689 A1
(43) Pub. Date: Jul. 10, 2025

(54) CVD PRECURSOR SUPPLY CONTAINER, METHOD OF REUSE THEREOF, AND PRECURSOR DEPOSITION METHOD

(71) Applicants: Mitsubishi Chemical Corporation, Tokyo (JP); Gelest, Inc., Morrisville, PA (US)

(72) Inventor: Hiroshi FUKUI, Tokyo (JP)

(21) Appl. No.: 18/965,645

(22) Filed: Dec. 2, 2024

Related U.S. Application Data
(60) Provisional application No. 63/619,463, filed on Jan. 10, 2024.

(51) Int. Cl. C23C 16/18; C23C 16/27

(52) U.S. Cl. CPC C23C 16/18; C23C 16/27

(57) ABSTRACT

A CVD container having excellent temperature controllability which ensures that a CVD precursor can be stably vaporized and supplied to a CVD apparatus is described. The CVD precursor supply container is adapted to vaporize a CVD precursor and supply the vaporized CVD precursor, and includes a metal container having a side portion of a double-wall structure including an inner tube and an outer tube each made of a metal, and a vacuum heat insulating layer provided between the inner tube and the outer tube.

### CROSS-REFERENCE TO RELATED APPLICATIONS

The present application claims the benefits of priority to U.S. provisional application No. 63/619,463, filed on Jan. 10, 2024, the entire disclosure of which is incorporated herein by reference.

### TECHNICAL FIELD

The present disclosure relates to a container to be used to supply a raw material compound (precursor) to a chemical vapor deposition (CVD) apparatus for formation of a thin film in a semiconductor production process and the like.

More specifically, the present disclosure relates to a container for storing a liquid or solid high-purity organometallic compound precursor without reducing the purity of the precursor, and then for vaporizing the precursor by bubbling or baking.

### BACKGROUND ART

In recent years, CVD film forming processes in precision production processes for information electronic materials, semiconductors and the like often require a liquid or solid high-purity precursor. It is highly desirable to prevent the reduction of the purity of the precursor and contamination of the precursor with impurities during the production phase and also during transportation and use.

Also desirable is a bubbling container and a baking container for supplying the precursor while vaporizing the precursor. In general, closed type containers unified with lids by integral molding or welding are currently available.

A precursor contained in such a bubbling container is heated to be vaporized by blowing inert gas into the container and, in this state, is transferred from the bubbling container into a CVD apparatus. At this time, vaporization heat is taken away, so that the container needs to be heated from the outside, for example, by a heater. Further, the amount of the precursor contained in the container is likely to be changed and, therefore, temperature control of the precursor is troublesome.

A container in which a chemical is stored for use in the production of semiconductor products is disclosed in the prior art (e.g., PTL 1), which includes a metal container having an interior surface coated with a polyperfluoroalkoxyethylene film for prevention of contamination with a contaminant. However, containers to be used for bubbling and baking must ensure that the precursor can be stably vaporized and supplied and, therefore, coating with a fluororesin is not necessarily suitable for a stable supply.

### RELATED ART DOCUMENT

### Patent Literature

PTL 1: JP-A-2015-534256

### SUMMARY OF THE INVENTION

In view of the foregoing, the present disclosure provides a container that has excellent temperature controllability, and ensures that a CVD precursor can be stably vaporized and supplied to the CVD apparatus.

In view of the foregoing, the inventor of the present disclosure conducted intensive studies and, as a result, found that, when a container has a side portion of double-wall structure including an inner tube and an outer tube, each made of a metal, and a vacuum heat insulating layer is provided between the inner tube and the outer tube, the precursor can be stably vaporized and supplied to a CVD apparatus associated with the supply of the precursor.

That is, embodiments of the present disclosure have the following features:

[1] A CVD precursor supply container adapted to vaporize a CVD precursor and supply the vaporized CVD precursor is provided, the CVD precursor supply containing comprising a metal container having a side portion of a double-wall structure including an inner tube and an outer tube each made of a metal, and a vacuum heat insulating layer provided between the inner tube and the outer tube.

[2] In the CVD precursor supply container according to [1], the metal container has a bottom to be heated by a heat source.

[3] In the CVD precursor supply container according to [1] or [2], the metal container has a lower bottom portion having an inverted truncated cone shape.

[4] In the CVD precursor supply container according to any one of [1] to [3], the metal container includes a container main body and a lid welded to the container main body.

[5] The CVD precursor supply container according to any one of [1] to [4] is a bubbling container, and further includes a nozzle through which an inert gas is introduced therein.

[6] In the CVD precursor supply container according to any one of [1] to [5], the metal container is made of an austenite stainless steel.

[7] In the CVD precursor supply container according to [6], the austenite stainless steel is a JIS-SUS316L stainless steel subjected to a vacuum double melting treatment, and the metal container has an electrolytically polished interior surface.

[8] The CVD precursor supply container according to any one of [1] to [7] further includes at least two diamond-like carbon layers provided on the interior surface of the metal container, wherein an innermost one of the diamond-like carbon layers is a tetrahedral amorphous carbon layer.

[9] In the CVD precursor supply container according to any one of [1] to [8], the CVD precursor is an organometallic compound that is a solid or a liquid at 25° C.

[10] In the CVD precursor supply container according to [9], the organometallic compound has a purity of not less than 95 mol %.

[11] In the CVD precursor supply container according to any one of [4] to [10], the lid has a hole through which the interior surface of the CVD precursor supply container can be observed with a borescope.

[12] In the CVD precursor supply container according to any one of [1] to [11], the metal container has a drain port provided in the bottom thereof for cleaning.

[13] A method of reusing the CVD precursor supply container according to any one of [1] to [12] is provided, the method comprising retaining a first precursor in the CVD precursor supply container, removing the first precursor from the CVD precursor supply container, cleaning the CVD precursor supply container with an acidic aqueous solution, and refilling the CVD precursor supply container with a second precursor.

[14] The method of reusing the CVD precursor supply container according to [13] further includes the step of cleaning the CVD precursor supply container with an alkali solution after the cleaning with the acidic aqueous solution.

[15] A precursor deposition method for depositing a substance by CVD is provided, which includes the steps of: vaporizing a CVD precursor by bubbling or baking in the CVD precursor supply container according to any one of [1] to [12]; supplying the vaporized precursor to a CVD apparatus; and depositing the precursor on a deposition object in the CVD apparatus.

### Effects of Disclosure

The CVD precursor supply container according to the present disclosure ensures that the precursor can be stably vaporized and supplied to the CVD apparatus.

### BRIEF DESCRIPTION OF DRAWINGS

FIG. 1 is an exploded perspective view showing a CVD precursor supply container according to one embodiment of the present disclosure.

FIG. 2 is a sectional view showing the CVD precursor supply container according to the embodiment of the present disclosure as a whole.

FIG. 3 is an explanatory diagram of a part of an A-A′ section of FIG. 1, showing that the peripheral wall of the container is coated with at least two diamond-like carbon layers different from each other.

### DESCRIPTION OF EMBODIMENTS

The present disclosure will hereinafter be described in greater detail based on specific embodiments, but the present disclosure is not limited to the following embodiments.

In the present disclosure, an expression “Y to Z” (wherein Y and Z are given numbers) means “not less than Y and not greater than Z” and is intended to also mean “preferably greater than Y” or “preferably less than Z” unless otherwise specified.

An expression “not less than Y” (wherein Y is a given number) or “not greater than Z” (wherein Z is a given number) is intended to also mean “preferably greater than Y” or “preferably less than Z.”

Further, an expression “x and/or y” (wherein x and y are given components) means “at least one of x and y” and, therefore, has three meanings including “x alone” “y alone” and “x and y.”

A CVD precursor supply container according to one embodiment of the present disclosure (hereinafter sometimes referred to simply as “the supply container”) is a bubbling or baking metal container to be used to vaporize a CVD precursor and supply the vaporized CVD precursor, and has a bubbling or baking function.

The term “CVD precursor” (hereinafter sometimes referred to simply as “precursor”) herein means a raw material compound to be used to form a thin metal film on a substrate by a chemical vapor deposition (CVD) method. The term “bubbling” herein means that a carrier gas is supplied into a liquid precursor to vaporize the precursor. The term “baking” herein means that a precursor that is liquid or solid at a normal temperature (e.g., 25° C.) is vaporized or sublimated by heating.

When the supply container is a bubbling container, the supply container typically includes a nozzle through which an inert gas or the like is introduced as the carrier gas thereto. Usable as the carrier gas for bubbling is a gas that is inert with respect to the precursor, and preferred examples of the inert gas include nitrogen, helium and argon.

In consideration that the supply container is used at higher temperatures, it is not preferred to provide a plastic coating on the interior surface of the supply container. The phase of the precursor to be used in this embodiment is not particularly limited, as long as the precursor can be vaporized by bubbling or baking, but a precursor that is a liquid or solid at normal temperature is typically used.

For bubbling, the precursor needs to be a liquid. When the precursor is a solid at normal temperature, the precursor preferably has a low melting point, preferably a melting point of 20° C. to 100° C., more preferably 25° C. to 60° C.

In general, examples of the precursor include inorganic compounds and organometallic compounds.

Examples of inorganic compounds include hydrides and halides. The inorganic hydride and the inorganic halide each have a high vapor pressure, and are gas or liquid at the normal temperature. Therefore, it is relatively easy to supply the inorganic hydride and the inorganic halide in a gas phase into the CVD apparatus. On the other hand, examples of organometallic compounds include alkoxy compounds, alkyl compounds and complex compounds.

These precursors each have a low vapor pressure, and are liquid or solid at the normal temperature. When any of these precursors is used for CVD, the precursor therefore needs to be vaporized.

Examples of appropriate precursors to be used in this embodiment include, without limitation: alkoxy-containing compounds such as tetraethoxysilane, triethyl phosphate, trimethyl borate, pentaethoxytantalum, tetra-t-butoxytin and isopropyl tri-t-butoxytin; alkyl-containing compounds such as trimethyl phosphite and trimethylaluminum; dialkylamino-containing compounds such as isopropyl tris(dimethylamino)tin, t-butyl tris(dimethylamino)tin, tetrakis(dimethylamino)tin and tetrakis(ethylmethylamino)tin; complex compounds such as bis(dipivaloylmethanato)strontium and tris(dipivaloylmethanato)bismuth; and liquefied ruthenium (“TRUST” available from Tanaka Kikinzoku Kogyo), lead zircon titanate (PZT), strontium bismuth tantalate (SBT), hexachlorodisilane and the like. These may be each used alone, or two or more of these may be used in combination.

Of these, the organometallic compound is required to have a high purity (not lower than 95 mol %) before film formation, and is mostly highly reactive with water vapor, oxygen and the like. Further, it is known that organic groups bonded to a metal are likely to be transposed to the same metal species or different metal species by transmetalation. In this process, the metal is likely to dissolve out. The organometallic compound is often decomposed by these impurities and, therefore, is required to have a very low metal impurity content. Further, when the organometallic compound has a hydrolyzable group, the organometallic compound is likely to be decomposed by reaction with water, thereby having a reduced purity. Therefore, strict gas tightness is required, and corrosion and contamination should be absolutely avoided. For these reasons, containers for these precursors are mostly of a sealed type with their lids welded thereto.

The organotin compound precursors can be used to form a film of metal oxo-hydroxo network with organic ligands by reaction with ultrapure water in the CVD apparatus for use as an EUV resist material. The organotin compound precursors are each typically required to have a purity of not lower than 95 mol %, preferably not lower than 99 mol %, because outgas is likely to be generated depending on the type of the impurity. The supply container is suitable for precursors that are likely to cause a problem even with a small amount of impurities.

### <Container Main Body>

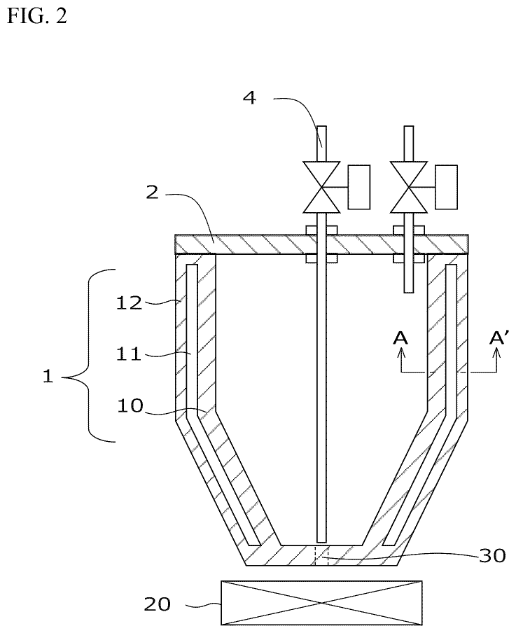

As shown in FIG. 2, for example, the supply container includes a container main body 1 made of a metal. The side portion of the container main body 1 has a double-wall structure including an inner tube 10 and an outer tube 12 each made of metal. A vacuum heat insulating layer 11 is provided between the inner tube 10 and the outer tube 12.

In the supply container, the precursor to be used in this embodiment needs to be heated for vaporization thereof and, therefore, a vacuum heat insulating layer 11 is required for prevention of heat dissipation. When the precursor is heated in the container main body 1 itself, a heater 20 or the like is typically used to heat the precursor through the bottom surface of the container main body 1. That is, the supply container is preferably configured so that the bottom of the container main body 1 is heated by a heat source, or is preferably used together with the heat source.

When the supply container is a bubbling container, the vapor pressure is likely to decrease due to the loss of vaporization heat because gas is inserted from the outside and causes bubbling when the vaporized or sublimated precursor is sent to the CVD device. The pressure change may result in a change in the supply amount of the precursor. Therefore, the vacuum heat insulating structure provided at least in the side wall can minimize heat dissipation.

Even if the container does not include a heat source for the vaporization of the precursor by bubbling, the bubbling vaporization can be achieved by preliminarily heating the precursor in a separate container and transferring the heated precursor to the supply container. If the vaporization heat is greater, however, the precursor often needs to be heated again and, therefore, the supply container preferably includes a heat source.

In this embodiment, the heat source (heater 20) is provided on the bottom of the container. If the input/output of heat is required, however, the heater 20 may be detachable from the bottom, and the vacuum portion of the side wall serves for heat retention. This method is also effective for a bubbling container and a baking container.

When the supply container is a baking container, no carrier gas is generally required because the container is directly heated to vaporize the precursor. However, a similar heat insulating container having a heat retaining effect is effective in keeping the temperature of the container at a constant level.

It is preferred that the side wall of the container main body 1 has a vacuum double-wall structure but the bottom wall does not have a vacuum double-wall structure for heat transfer.

Exemplary production methods for the inner tube 10 and the outer tube 12 defining the vacuum double-wall structure include an integral forming method such that a single metal plate is bent, and a welding method such that the inner tube and the outer tube are separately formed and are welded to a bottom component.

The thicknesses of the peripheral wall and the bottom wall of the supply container are properly set according to the desired overall size and the overall shape of the supply container. Further, the thicknesses of the inner tube 10, the outer tube 12, and the vacuum heat insulating layer 11 defining the vacuum double-wall structure of the supply container are properly set according to the desired size and the shape of the supply container. The thickness of the inner tube 10 and the thickness of the outer tube 12 may be the same, but the thickness of the inner tube 10 is preferably greater than the thickness of the outer tube 12 in order to prevent minute deformation or the like of the container, which may otherwise occur due to pressure.

When the interior surface of the supply container is electrolytically polished or formed with a coating layer such as a diamond-like carbon (DLC) layer, the interior surface is preferably as smooth as possible in order to ensure firm adhesion of the coating layer to the interior surface. For example, the interior surface preferably has a surface roughness Ra of not greater than 0.1 μm, more preferably not greater than 0.08 μm.

The surface roughness Ra is a height parameter (arithmetic average roughness) specified in JIS-B0601. The aforementioned surface roughness can be achieved, for example, by polish-finishing, such as electrolytic polishing or buff polishing. In general, when the interior surface is electrolytically polished, a DLC layer is not formed.

Further, when the container is of a completely sealed type and is not disposable, a container interior surface test is performed to ensure high purity of the precursor when the container is refilled with the precursor. Therefore, the supply container preferably has a hole formed in the ceiling wall (lid) thereof so that the interior surface can be observed with a borescope.

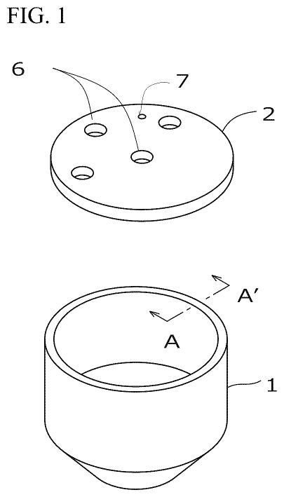

The supply container will be described specifically by way of preferred embodiment. As shown in FIG. 1, for example, the supply container is a CVD precursor supply container for semiconductor production, which includes a container main body 1 having a hollow cylindrical side portion and a lower bottom portion having an inverted truncated cone shape, and a lid 2 sealingly closing the upper opening of the container main body 1. These components may be unified by welding or the like.

The inner recess of the container main body 1 serves as a chemical accommodating space.

The lower bottom portion of the interior surface (recess) of the container main body preferably has an inverted truncated cone shape (or an inverted cone shape). The container side portion typically has a hollow cylindrical shape and, therefore, the overall shape of the container is preferably like a so-called hopper. The container bottom surface is preferably flat. This reduces the amount of precursor left unused, and facilitates cleaning of the container. Further, this minimizes the exposure of the interior surface to an external environment, and minimizes the contamination of the interior surface with foreign matter and corrosion of the interior surface.

The lowermost portion of the supply container may have a drain port (as indicated, for example, by 30 in FIG. 2). The provision of the drain port ensures sufficient cleaning even if the precursor is partly left unused. Further, scale is likely to stick to the inside of the container during cleaning, depending upon the type of precursor employed. In this case, the inside of the container is preferably cleaned with an acidic aqueous solution, such as dilute hydrofluoric acid, every few cleaning cycles. When the inside of the container is finish-cleaned with ultrapure water repeatedly to address the metal dissolution due to dilute hydrofluoric acid, the presence of the drain port in the bottom portion is advantageous. The drain port makes it possible to circulate ultrapure water from the container, and prevents recontamination (with an external substance or an outer surface metal), which may otherwise occur when the water (containing hydrofluoric acid) overflows to the outside of the container (and which may result in dissolution of the container).

The drain port is provided with a plug, which is preferably flush with the interior surface of the container so as to prevent a residue from remaining around the drain port.

If the supply container is to be provided with an open/close juncture of the lid 2, a packing or a gasket is provided. When the lid 2 is opened and closed, therefore, the contamination is likely to occur due to the packing, the gasket, and other foreign matter from the external environment. Therefore, the supply container is preferably sealable with the lid 2 to ensure the storage stability of the precursor to be used.

When the container main body 1 and the lid 2 are integrally formed, it is impossible to coat the container interior surface with diamond-like carbon (DLC) or the like. Therefore, in such cases, the container main body 1 and the lid 2 are separately produced, and the container interior surface and the like are coated. Then, the lid 2 is attached to the container main body 1. For enhancement of the sealability of the container, the container main body 1 and the lid 2 are combined together, preferably by welding, more preferably by inlay (spigot) welding that prevents detachment of the lid.

The material for the container main body 1 and the lid 2 is a metal. Examples of the metal include iron, copper, aluminum, alloys of these metals, and alloys of any of these metal with some other metal. Of these, austenite stainless steel, which is an iron-based alloy, is preferred for smooth finishing of the interior surface. More preferably, JIS-SUS316 stainless steel or JIS-SUS304 stainless steel is used, and JIS-SUS316L stainless steel subjected to a vacuum double melting treatment is most preferably used. Further, the container interior surface is preferably electrolytically polished for preventing corrosion of the metal of the container by the precursor, or the container interior surface is preferably coated with DLC for preventing transmetalation and corrosion by the acid during the cleaning.

Thus, a CVD precursor supply container can be provided, which is capable of heating, retaining heat, and minimizing chemical residue, and which is free from electrification and is cleanable and reusable.

### <Electrolytically Polishing>

In an electrolytic polishing solution, a container formed of the JIS-SUS316L stainless steel subjected to vacuum double melting treatment is used as an anode and direct current is applied to the container, whereby the surface of the container is electrochemically dissolved to a depth of several microns. At this time, metal projections of the container interior surface are dominantly dissolved due to the property of the electrolytic polishing solution. Thus, a smooth and lustrous surface is provided. Since iron in the stainless steel surface is selectively dissolved, the surface is chromium-rich and thereby improved in corrosion resistance.

When the precursor is an organometallic compound, corrosion of the metal of the container is often problematic. When the precursor is an organotin compound, for example, stanoxane or the like is generated. If stanoxane is deposited (as scale) to stick to the metal surface, stanoxane can be cleaned away with the use of an acid. If hydrofluoric acid or high-concentration nitric acid is used, the electrolytically polished stainless steel surface is likely to be corroded. In this case, the stainless steel surface is preferably coated.

When the metal surfaces of the container main body 1 and the lid 2 are not coated, i.e., when the contents of the container are in direct contact with the metal of the container, the metal is likely to dissolve from the container, particularly due to the acidic aqueous solution that may be used for cleaning. Therefore, it is desirable that the interior surface is coated with a corrosion resistant coating, and that a JIS-SUS316L stainless steel, (an austenite stainless steel material) subjected to a vacuum double melting treatment and thereby having a generally minimum trace-metal content is selected as the interior surface metal.

A layer formed of a diamond-like carbon (DLC layer) is preferably used as a coating layer formed on the metal interior surface. In consideration that acid cleaning is performed for reusing the container, the container surface to be brought into contact with the acidic cleaning agent preferably has corrosion resistance.

### [Coating Layer of DLC]

The coating layer covering the interior surface of the container main body 1 is preferably a DLC layer. The DLC layer may have a single layer structure or a multilayer structure including two or more layers stacked one on another.

The DLC layer has better wear resistance, heat resistance, corrosion resistance, and pinhole resistance, is easier to clean, and is less susceptible to electrification than a plastic coating surface (e.g., a fluororesin coating surface). With the intervention of a DLC layer between the metal container main body 1 and the precursor, the precursor retained in the recess is prevented from being contaminated with foreign matter.

The term “DLC” of the DLC layer covering the interior surface of the container main body 1 is a general term for substances containing carbon as a main component and having both a diamond carbon-carbon bond (sp³) and a graphite carbon-carbon bond (sp²) (and often means a thin film formed of such a substance). The term “main component” herein means a component contained in the greatest proportion among other components. The proportion of the main component is typically not less than 50 mass %, preferably not less than 80 mass %, more preferably not less than 90 mass %, or may be 100 mass %, based on the overall mass.

A structure including both a diamond bond and a graphite bond is generally referred to as an amorphous structure, and a DLC layer is a carbon film including both a sp³ bond and a sp² bond. Therefore, the DLC film is also referred to as an amorphous carbon film.

As for the sp³/sp² ratio of the DLC composition, a DLC having a higher sp³ ratio and hence having a property closer to that of diamond is referred to as “ta-C (tetrahedral amorphous carbon)” and a DLC having a higher sp² ratio and hence having a property closer to that of graphite is referred to as “a-C (amorphous carbon).” DLCs obtained by incorporating hydrogen atoms to such DLCs are respectively referred to as “ta-C:H (hydrogenated tetrahedral amorphous carbon)” and “a-C:H (hydrogenated amorphous carbon)” and tend to have excellent friction coefficient reducing effects.

The DLC layer is imparted with various physical properties by adjusting the proportion of hydrogen atoms to be incorporated in the crystalline structure, the sp³/sp² ratio, and the presence/absence and the proportions of other elements. Particularly, an innermost DLC layer (to be brought into contact with the chemical) is preferably a ta-C DLC layer.

The DLC layer covering the interior surface of the container main body 1 has a thickness of 50 to 15,000 nm, preferably 100 to 10,000 nm, more preferably 500 to 5,000 nm, still more preferably 1,000 to 3,000 nm, in view of the effects of the present disclosure.

### [At Least Two Different DLC Layers]

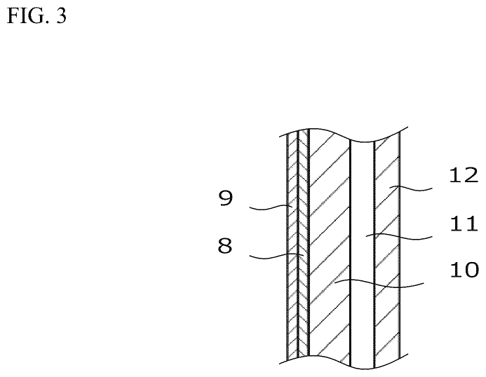

When the DLC layer includes at least two different DLC layers, the DLC layer covering the interior surface of the container main body 1 may have a multilayer structure including two or more DLC layers stacked one on another. In this embodiment, as schematically shown in FIG. 3 which is a sectional view taken along A-A′ in FIG. 1, the interior surface is covered, for example, with a first DLC layer 8 and a second DLC layer 9.

The DLC layers including a first DLC layer 8 and a second DLC layer 9 are sometimes referred to collectively as “DLC coating layer.”

The DLC coating layer preferably includes two or more DLC layers that are different in hydrogen atom content and/or sp³/sp² ratio. By coating the interior surface with the two or more different DLC layers, the interior surface is imparted with various physical properties, such as higher hardness, wear resistance, color tone, and corrosion resistance to the chemical liquid to be brought into contact with the interior surface. Thus, high purity of the precursor can be maintained even during long-term storage and transportation. Since the metal surface of the supply container is not exposed, the inside of the supply container can be repeatedly cleaned with the acidic aqueous solution. Therefore, the supply container is suitable for reuse.

As a result, high-quality semiconductor products can be stably provided by handling the precursor (as a chemical for semiconductor production) by using the supply container.

With a single DLC layer, it may be impossible to sufficiently ensure adhesion and pinhole resistance, depending upon the combination of the type of the DLC and the type of interior surface metal of the container main body 1. Therefore, it is preferred that a DLC layer having excellent adhesion to metals (first DLC layer 8) is provided in contact with the interior surface of the container main body 1, and a DLC layer having excellent various properties required to maintain the purity of the precursor (second DLC layer 9) is provided on the first DLC layer.

With a single DLC layer, it may be impossible to ensure a lower light reflectance and a color suitable for the test to be performed using a borescope, depending upon the combination of the type of the DLC and the type of interior surface metal of the container main body 1. Therefore, at least one of the DLC layers is preferably a DLC layer having a property closer to that of the graphite structure having a higher sp² ratio, and this DLC layer is more preferably provided in contact with the interior surface of the container main body 1. The DLC having a higher sp² ratio has a dark black color and has a reduced light reflectance, thereby making it easier to perform a cleaning residue test using a borescope as compared with a metal interior surface and fluororesin coating.

FIG. 3 shows a DLC layer structure including two layers, i.e., a first DLC layer 8 and a second DLC layer 9. When more than two DLC layers are stacked one on another, these DLC layers can produce combinational effects.

In this embodiment, a DLC that is relatively flexible, has excellent adhesion to the metal surface, and has a property closer to that of graphite (black lead) is preferably used for the first DLC layer 8. Specifically, a-C (amorphous carbon) is preferred, and a-C:H (hydrogenated amorphous carbon) having a hydrogen atom content of 20 to 40 atom %, more preferably 25 to 35 atom %, is particularly preferred. In terms of flexibility, a DLC having a hardness Hv of 1,000 to 4,000 is preferred. ADLC having such properties has a dark black color, facilitating observation using a borescope.

The DLC layers preferably have a total thickness of 1,000 to 15,000 nm, more preferably 1,000 to 10,000 nm.

The first DLC layer 8 typically has a thickness of 500 to 10,000 nm, more preferably 2,000 to 10,000 nm, depending upon the overall size and the wall thickness of the container main body 1. That is, if the thickness of the first DLC layer 8 is too small, the conformability of the overall DLC coating layer to the surface roughness of the interior surface of the container main body 1 tends to be reduced. When the thickness of the first DLC layer falls within the aforementioned range, the effects tend to be efficiently provided.

Further, a DLC that is relatively hard and has poorer adhesion to the metal surface but has excellent wear resistance, corrosion resistance, and pinhole resistance and has a property closer to that of the diamond is preferably used for the second DLC layer 9. Specifically, a tetrahedral amorphous carbon (ta-C) containing no hydrogen atom or having a hydrogen atom content of not greater than 5 atom % is preferred. As for the hardness, a DLC having a hardness Hv of 4,000 to 7,000 is preferred. For wear resistance, a DLC having a dynamic friction coefficient μ of not greater than 0.15 on its surface is preferred, and a DLC having a dynamic friction coefficient μ of not greater than 0.1 on its surface is more preferred. The lower limit of the dynamic friction coefficient μ is typically 0.

The second DLC layer 9 preferably has a physical property such that static electricity is less likely to occur on the surface of an insulator, such as of a fluororesin with a volume resistivity of not less than 10¹⁸ Ω·cm and, therefore, preferably has a volume resistivity of not greater than 10¹⁰ Ω·cm. Considering that a surface having a lower water repellency can be easily cleaned, the second DLC layer 9 preferably has a surface having a water repellency (water contact angle) of 50° to 80° (for reference, the fluororesin has a contact angle of not less than 100°).

The second DLC layer 9 preferably has a thickness of 50 to 5,000 nm, more preferably 100 to 3,000 nm. The thickness of the second DLC layer 9 depends upon the physical properties (e.g., hydrogen atom content and the like) of the first DLC layer 8.

The second DLC layer 9 is very hard and therefore more difficult to form into a thick film, and therefore may have a multilayer structure. By adjusting the hydrogen atom content of the first DLC layer 8, an excellent precursor purity maintaining effect of the DLC tends to be sufficiently and efficiently ensured.

When the DLC coating layer has a double layer structure or has a multilayer structure including two or more DLC layers, the DLC coating layer has an overall thickness of 1,000 to 15,000 nm. A preferred thickness depends upon the properties of the respective layers. That is, the preferred thickness depends upon a composition classification (based on the hydrogen atom content and the sp³/sp² ratio).

If the thickness of the DLC coating layer is too low, as described above, the DLC coating layer tends to fail to sufficiently exhibit the properties of the DLC. When the thickness of the DLC coating layer falls within the aforementioned range, the DLC coating layer tends to efficiently provide the effects. When the DLC coating layer has a multilayer structure, the surface layer of the DLC coating layer (to be brought into contact with the precursor) is desirably a DLC layer having substantially the same property as the second DLC layer 9.

The DLC coating layer can be formed by a film formation method selected from known film formation methods according to the types of the DLCs. Specific examples of the film formation method are as follows. When two or more DLC layers are formed from different types of DLCs, as in this embodiment, and the same film formation method is used for the formation of the two or more DLC layers, the DLC layers can be sequentially formed using a single apparatus by changing the film formation materials.

### (1) CVD (Chemical Vapor Deposition) Method

Thermal CVD method
Plasma CVD method (radio frequency, microwave, direct current and the like)

### (2) PVD Method (Physical Vapor Deposition)

Ion plating (direct current excitation, radio frequency excitation)
Sputtering method (dipole sputtering, magnetron sputtering, ECR sputtering)
Laser ablation method
Ion beam deposition
Ion implantation method

Of these methods, the plasma CVD method is preferred. More preferably, the plasma CVD method employs radio frequency pulse (RF) at 5 to 15 MHz (including a HF band of 13.56 MHz) and an output of 10 to 1,000 W, still more preferably 300 to 500 W.

In the supply container, as described above, at least the metal interior surface of the container main body 1 in which the chemical is retained is preferably coated with the coating layer including the DLC layers 8, 9. Thus, the interior surface has excellent wear resistance, heat resistance, corrosion resistance, and pinhole resistance, and is easy to clean and less susceptible to electrification than a fluororesin coating surface or the like. As a result, when the chemical for the semiconductor production is stored or transported in the supply container for a long period of time, the metal of the container main body 1 is prevented from dissolving into the chemical, from peeling off, or from being electrified and resulting in the contamination of the chemical.

### [Fluororesin Coating]

The fluororesin coating is a surface treatment that imparts a component surface with various intrinsic properties of the fluororesin (excellent non-adhesiveness, water repellency and slidability, corrosion resistance, a higher heat resistant temperature, and the like) for prevention of sticking and adhesion, for reduction of friction, and for protection of the components. Particularly preferred examples of the coating material for semiconductor products include PTFE and PFA. These coating materials have excellent properties, but are poorer in electrification and heat resistance than the metal and the DLC coating. When the fluororesin is heated to a high temperature, fluorine oxide is likely to evaporate. A fluororesin coating layer may be provided on the same portion as the DLC coating layer. In this embodiment, the fluororesin coating layer preferably has a thickness of 1 to 15 μm for corrosion resistance.

### <Lid>

Next, the lid 2 according to this embodiment will be described in detail.

The metal for the lid 2 is preferably the same as that for the container main body 1. However, the same material is not necessarily required to be used for the container main body 1 and for the lid 2. The lid 2 may have an inlay structure such as not to allow for opening and closing, or may have an integral structure.

The lower surface of the lid 2 (facing the upper opening of the container main body 1) is preferably subjected to electrolytic polishing in the same manner as the container main body 1 so that the purity of the chemical can be maintained in the container.

The lower surface of the lid 2 is preferably provided with a coating layer to maintain the purity of the chemical in the container. The coating layer provided on the lid 2 is not necessarily required to be the same as the coating layer provided on the container main body 1, but is preferably the same as the coating layer provided on the container main body 1.

The lid 2 typically has a precursor inlet port, a vaporized precursor outlet port, level sensor holes 6, an electrode attachment hole 7 and the like provided at predetermined positions. A hole through which the container interior surface is observed by a borescope may be selected from available holes.

When the container is of the completely sealed type and is not disposable, the container interior surface test is performed using the borescope or the like to ensure the high purity of the precursor when the container is refilled with the precursor.

When the supply container is a bubbling container, the lid 2 is also provided with an inert gas inlet port. In this case, the inert gas inlet port may double as the precursor inlet port for refilling.

The inner peripheral surfaces of the holes 6, 7 and the like of the lid 2 may be treated in the same manner as the lower surface of the lid 2 by electrolytic polishing, and respectively formed with coating layers. Thus, the inner peripheral surfaces of the holes 6 and the like are smoothed. This is more advantageous because metal dust is not generated and external dust is less likely to be attracted when pipes and an electrode are attached to and detached from the container.

When a component corresponding to the lid 2 is incorporated as a part of a precursor supply system and the container main body 1 is used alone, only the container main body serves as the CVD precursor supply container according to this embodiment.

### <Method of Reusing Supply Container>

The supply container is excellent in wear resistance and corrosion resistance and, therefore, can be reused by cleaning the container after use. In a method of reusing the supply container to be refilled with a new precursor after use, the container is preferably cleaned with a cleaning liquid before being refilled with the precursor. This makes it possible to ensure the high purity of the precursor.

Conceivable chemicals to be used as the cleaning liquid are the following chemicals, for example, which are fluid liquids.

Examples of such chemicals include: hydrocarbon solvents such as hexane and heptane; alcohol solvents such as methanol, ethanol, and isopropanol; and acidic aqueous solutions such as nitric acid aqueous solution and hydrofluoric acid aqueous solution. Of these, the acidic aqueous solutions are preferred. These may be each used alone, or two or more of these may be used in combination.

When the interior surface of the supply container is coated with a DLC coating layer, a hydrofluoric acid aqueous solution and/or a high-temperature nitric acid aqueous solution are preferably used. The concentration of the chemical in the aqueous solution is preferably 0.1 to 40 mass %.

Since metal dissolution is likely to occur due to the acidic aqueous solution used for cleaning, the interior surface of the container is preferably coated with a DLC coating layer, a fluororesin coating, or other corrosion resistant coating.

When the precursor is likely to generate scale (e.g., when the precursor is an organotin compound), it is preferable to clean the inside of the container with an alkali solution after cleaning with the acidic aqueous solution. A preferred example of an alkali solution is a sodium hydroxide solution that facilitates the removal of scale and the like. Thus, dirt that cannot be removed with an acidic aqueous solution can be removed by cleaning with the alkali solution.

### <Precursor Depositing Method>

In the supply container, the precursor is vaporized by bubbling or baking, and the vaporized precursor is stably supplied to the CVD apparatus, whereby the uniform and homogeneous deposition of the precursor can be achieved in the CVD apparatus.

Therefore, the supply container can be repeatedly used to handle the precursor, whereby high-quality semiconductor products can be stably provided.

### Applicability

The supply container has excellent wear resistance, corrosion resistance, heat resistance, and heat retaining properties. Therefore, the supply container is suitable for a precursor that is a liquid or a solid having a lower melting point and having a vapor pressure to be vaporized by heating in the container and supplied to the CVD apparatus. The supply container is advantageously used as a bubbling container or a baking container for the storage and the transportation of the precursor.

When the supply container is used for storage, the supply container is filled with a mixture of the precursor and a noble gas (of the same type as that used for the bubbling or some other noble gas), whereby the precursor can be stored. The precursor can thus be stored and preserved for a predetermined period of time or transported.

### <Supply Container>

The supply container is configured such that the container side portion is provided with a vacuum heat insulating layer and heat can be inputted and outputted through the container bottom portion. When the precursor is heated through the container bottom portion for baking or bubbling, for example, heat transfer is facilitated, thereby stabilizing the temperature of the precursor in the supply container. Since there is a possibility that the supply container is heated to a high temperature, the stainless steel components of the supply container are preferably provided with no plastic coating.

For the prevention of metal dissolution, therefore, austenite stainless steel, particularly JIS-SUS316L stainless steel subjected to a vacuum double melting treatment, is preferably used as the material for the supply container. Further, electrolytic polishing is preferably performed on the container interior surface for prevention of metal dissolution, or the container interior surface is preferably coated with at least the two or more DLC layers to minimize metal dissolution. Particularly, when the container interior surface is coated, from the viewpoint of reuse, the inside of the supply container can be cleaned, for example, with a 40% nitric acid aqueous solution or a hydrofluoric acid solution having a desired concentration when the precursor is solidified (to form scale) in the supply container.

In addition, the supply container has a hopper-like container shape, and the container main body 1 has a bottomed hollow cylindrical shape, allowing for easy cleaning. Therefore, the inside of the supply container can be cleaned in a short period of time, allowing for easy handling of the container for a chemical changing operation and the like. Since the container interior surface is coated with DLC layers, the inside of the container is less susceptible to electrification. Therefore, the supply container is advantageous in that dust and the like are less likely to enter the container from the outside when the lid 2 is opened and closed. Since the chemical liquid is less likely to accumulate in the supply container and the residue of the content substance is less likely to remain in the supply container, a residue test can be optimally performed in the supply container using a borescope after cleaning. Therefore, the supply container can be repeatedly used to handle a chemical for semiconductor production, whereby high-quality semiconductor products can be stably provided. Further, the supply container eliminates a risk that the precursor is stored or transported with some residue present in the supply container. In addition, the supply container can be efficiently cleaned and reused.

In the supply container, at least the side portion of the chemical retaining portion of the container main body 1 has a vacuum double-wall structure. Therefore, the supply container ensures easy heating and excellent heat retaining properties. Further, the supply container has a bottomed hollow cylindrical shape, so that cleaning residues can be minimized. The container interior surface is coated with DLC layers and, therefore, is free from electrification. Thus, the supply container can be repeatedly cleaned and reused substantially without contamination with foreign matter from the outside. When the container interior surface is electrolytically polished, the supply container has excellent corrosion resistance.

Therefore, the metal of the container main body 1 is unlikely to dissolve into the precursor, to peel off, or to be electrified and result in the contamination with the foreign matter when the precursor is stored or transported in the container for a longer period of time.

In the supply container, as described above, the lower surface of the lid 2 may be provided with a coating layer. Further, the inner peripheral surfaces of the holes 6, 7 and the like through which the pipes, the liquid surface level sensor 4, and the electrode are attached to the lid 2 may be each provided with a DLC coating layer in the same manner as the lower surface of the lid 2. Regarding the coating layers, the inner peripheral surfaces of the holes 6 and the like are smoothed. This is more advantageous because metal dust is not generated and external dust is less likely to be attracted when the pipes and the electrode are attached to and detached from the container.

Thus, when the container according to this embodiment is used for the supply of a chemical in a CVD process, the production of defective products can be prevented, which may otherwise occur due to the reduction of the purity of the chemical. This makes it possible to produce high-quality semiconductor products with a higher yield.

### EXAMPLES

The present disclosure will be described specifically by way of examples. It should be understood that the present disclosure be not limited by the following examples.

### Example 1

First, as shown in FIG. 2, a container is prepared, including a container main body 1 having a side portion of a double-wall structure including an inner tube 10 and an outer tube 12, and a vacuum heat insulating layer 11 provided between the inner tube 10 and the outer tube 12. The vacuum heat insulating layer 11 is sealed by a bottom portion (with the side portion welded to the bottom portion). The peripheral wall (side portion) of the container main body 1 has a total thickness of 11 mm with the thicknesses of the inner tube 10, the vacuum heat insulating layer 11 and the outer tube 12 being 5 mm, 3 mm and 3 mm, respectively.

The container including the container main body 1 and the lid 2 is produced from a JIS-SUS316L stainless steel subjected to a vacuum double melting treatment.

The outer shape of the container main body 1 is such that the upper portion thereof has a cylindrical shape and the lower bottom portion thereof has an inverted truncated cone shape. The cylindrical upper portion has a diameter of 140 mm, and the lowermost bottom portion has a diameter of 70 mm. The total height of the cylindrical upper portion and the lower bottom portion is 110 mm (the cylindrical shape of the upper portion having a height of 60 mm and the inverted truncated cone shape of the lower bottom portion having a height of 50 mm). The bottom wall has a thickness of 13 mm, and the peripheral wall has a thickness of 11 mm. The chemical retaining recess has an internal volume of 1,200 mL. The bottom interior surface of the container main body 1, the lower surface of the lid 2, and the inner peripheral surfaces of the holes 6, 7 and the like (see FIG. 1) are electrolytically polished.

### Example 2

Unlike in Example 1, the bottom interior surface and the like of the container main body 1 are not electrolytically polished, but are polished with a water-resistant abrasive paper (#1200) and a polishing buff (0.05-μm alumina) and then subjected to a degreasing treatment with acetone to be finished to a surface roughness Ra of not greater than 0.02 μm.

Then, a first DLC layer and a second DLC layer are formed in this order on the bottom interior surface of the container main body 1, the lower surface of the lid 2, and the inner peripheral surfaces of the holes 6, 7 by a plasma CVD method (with radio frequency pulse at 10 MHz and an output of 400 W using a material gas containing acetylene and octafluoropropane mixed at a ratio of 1:1). Thereby, as shown in FIG. 3 which is a sectional view taken along A-A′ in FIG. 2, a container with its interior surface coated with a first DLC layer 8 and a second DLC layer 9 is provided. The details of the respective layers are as follows:

(1) First DLC Layer (in Contact with Metal Surface)
Type of DLC: a-C:H (having a hydrogen atom content of 30% and a hardness Hv of 2,000)
Layer thickness: 9,000 nm
   (2) Second DLC Layer (to be Brought into Contact with Chemical)
Type of DLC: ta-C (having a hydrogen atom content of not greater than 5%, a hardness Hv of 6,000, a layer surface dynamic friction coefficient (μ) of 0.1, a volume resistivity of 10⁹ Ω·cm, and a water repellency (water contact angle) of) 80°)
Layer thickness: 1,000 nm

### Comparative Example 1

A container having no coating layer is produced in substantially the same manner as in Example 1, except that the peripheral wall of the container main body 1 had a single-wall structure having a thickness of 9 mm (with no vacuum heat insulating layer).

### Comparative Example 2

A container with a coating layer is produced in substantially the same manner as in Example 2, except that the peripheral wall of the container main body 1 has a single-wall structure having a thickness of 9 mm (with no vacuum heat insulating layer), and the bottom interior surface of the container main body 1, the lower surface of the lid 2, and the inner peripheral surfaces of the holes 6, 7 are not coated with a first DLC layer 8 and a second DLC layer 9 but coated with a polyperfluoroalkoxyethylene resin (fluororesin) layer (having a fluororesin layer thickness of 15 μm).

The products according to these examples and comparative examples are evaluated for the following properties, and the evaluation results are shown below in Table 1.

### <Evaluation for Supply Stability>

An organotin precursor Sn(NEtMe)₄ is supplied at 760 torr to a CVD apparatus from the container while being heated to 250° C. in the container through the bottom portion of the container. At this time, the container is evaluated for supply stability based on the following criteria:
∘ (Very good): Stable supply to the CVD apparatus is possible.
x (Bad): Stable supply to the CVD apparatus is impossible.

In Examples 1 and 2, a continuous supply at a stable temperature is possible. In Comparative Examples 1 and 2, in contrast, it is impossible to supply the precursor at a constant rate to the CVD apparatus with difficulty in temperature control.

### <Evaluation for Cleanability>

The container is cleaned with hydrofluoric acid (1% aqueous solution), and refilled with the precursor. At this time, the container is evaluated for cleanability based on the following criteria to determine whether or not the container is reusable while ensuring the high purity of the precursor.
∘ (Very good): It is possible to sufficiently clean the container and to ensure high purity.
Δ (Good): It is possible to sufficiently clean the container, but impossible to ensure high purity.
x (Bad): The cleaning is insufficient (the cleaning is insufficient due to water repellency, making it difficult to remove foreign matter intruding into a layer peel-off portion or scratches).

In Comparative Example 2, stained foreign matter is detected in minute scratches formed in the fluororesin coating, and it is difficult to wash away the foreign matter with cleaning water due to water repellency. The foreign matter would be removed by fully filling the container with nitric acid or hydrofluoric acid aqueous solution. In Comparative Example 1, the metal dissolves into the precursor, resulting in contamination.

In Example 2, in contrast, the interior surface is coated with DLC layers, making it possible to easily clean away the foreign matter with nitric acid and hydrofluoric acid aqueous solution. After cleaning with hydrofluoric acid, it is possible to ensure high purity of the precursor by sufficiently cleaning with sodium hydroxide.

### <Evaluation for Wear Resistance>

The container is evaluated for wear resistance based on the following criteria when the liquid surface level sensor is inserted into and removed from the container after the container is cleaned so as to be refilled with the precursor.

After the container main body 1 and the lid 2 are cleaned and the liquid surface level sensor 4 (shown in FIG. 2) is repeatedly inserted into and removed from the liquid surface level sensor attachment hole of the lid 2 a hundred times, the inner peripheral surface of the hole is visually observed. Then the container is evaluated based on the following criteria:
∘ (Very good): The inner peripheral surface is kept intact without any scratch or any peel-off portion.
Δ (Good): There are scratches but visually imperceptible.
x (Bad): Scratches, peel-off portions and the like are observed.

In Comparative Example 2, minute scratches are visually observed on the inner peripheral surface of the hole of the lid 2. In Example 2, in contrast, the inner peripheral surface of the hole of the lid 2 of the container is kept as intact as initially observed, without any scratches.

TABLE 1

| | | | Com- | Com- |
|---|---|---|---|---|
| | | | parative | parative |
| | Example 1 | Example 2 | Example 1 | Example 2 |
| Wall | Double-wall | Double-wall | Single-wall | Single-wall |
| structure | structure | structure | structure | structure |
| Layer | None | Two DLC layers | None | Fluororesin |
| composition | (Electro- | 1st DLC: | (Electro- | |
| | lytically | a-C:H | lytically | |
| | polished) | 2nd DLC: ta-C | polished) | |
| Supply | ○ | ○ | × | × |
| stability | | | | |
| Cleanability | Δ | ○ | Δ | × |
| Wear | ○ | ○ | ○ | × |
| resistance | | | | |

While specific forms of the embodiments of the present disclosure have been shown in the above examples, the examples are merely illustrative but not limitative. It is contemplated that various modifications apparent to those skilled in the art could be made within the scope of the present disclosure.

### DESCRIPTION OF REFERENCE CHARACTERS

1: Container main body
2: Lid
8: First DLC layer
9: Second DLC layer
10: Inner tube
11: Vacuum heat insulating layer
12: Outer tube
20: Heater
30: Drain port

1. A CVD precursor supply container adapted to vaporize a CVD precursor and supply the vaporized CVD precursor, the CVD precursor supply container comprising a metal container having a side portion of a double-wall structure including an inner tube and an outer tube each made of a metal, and a vacuum heat insulating layer provided between the inner tube and the outer tube.

2. The CVD precursor supply container according to claim 1, wherein the metal container has a bottom to be heated by a heat source.

3. The CVD precursor supply container according to claim 1, wherein the metal container has a lower bottom portion having an inverted truncated cone shape.

4. The CVD precursor supply container according to claim 1, wherein the metal container comprises a container main body and a lid welded to the container main body.

5. The CVD precursor supply container according to claim 1, wherein the container is a bubbling container, the CVD precursor supply container further comprising a nozzle through which an inert gas is introduced therein.

6. The CVD precursor supply container according to claim 1, wherein the metal container is made of an austenite stainless steel.

7. The CVD precursor supply container according to claim 6, wherein the austenite stainless steel is a JIS-SUS316L stainless steel subjected to a vacuum double melting treatment, and wherein the metal container has an electrolytically polished interior surface.

8. The CVD precursor supply container according to claim 1, further comprising at least two diamond-like carbon layers provided on an interior surface of the metal container, wherein an innermost layer of the at least two diamond-like carbon layers is a tetrahedral amorphous carbon layer.

9. The CVD precursor supply container according to claim 1, wherein the CVD precursor is an organometallic compound that is a solid or a liquid at 25° C.

10. The CVD precursor supply container according to claim 9, wherein the organometallic compound has a purity of not less than 95 mol %.

11. The CVD precursor supply container according to claim 4, wherein the lid has a hole through which an interior surface of the CVD precursor supply container can be observed with a borescope.

12. The CVD precursor supply container according to claim 1, wherein the metal container has a drain port provided in a bottom thereof for cleaning.

13. A method of reusing the CVD precursor supply container according to claim 1, the method comprising retaining a first precursor in the CVD precursor supply container, removing the first precursor from the CVD precursor supply container, cleaning the CVD precursor supply container with an acidic aqueous solution, and refilling the CVD precursor supply container with a second precursor.

14. The method of reusing the CVD precursor supply container according to claim 13, further comprising a step of cleaning the CVD precursor supply container with an alkali solution after the cleaning with the acidic aqueous solution.

15. A precursor deposition method for depositing a substance by CVD comprising the steps of: vaporizing a CVD precursor by bubbling or baking in the CVD precursor supply container according to claim 1; supplying the vaporized precursor to a CVD apparatus; and depositing the precursor on a deposition object in the CVD apparatus.
